(19) United States
(12) Patent Application Publication
(10) Pub. No.: US 2018/0053735 A1
(43) Pub. Date: Feb. 22, 2018

(54) WIRELESS MODULE

(71) Applicant: Murata Manufacturing Co., Ltd., Kyoto (JP)

(72) Inventor: Hideki Ueda, Kyoto (JP)

(21) Appl. No.: 15/679,588

(22) Filed: Aug. 17, 2017

(30) Foreign Application Priority Data
Aug. 22, 2016 (JP) 2016-161614

(51) Int. Cl. H01L 23/66; H01Q 9/40; H01Q 9/06; H01Q 9/04; H01R 12/72; H01R 24/50

(52) U.S. Cl. CPC H01L 23/66; H01Q 9/40; H01Q 9/065; H01Q 9/0485; H01R 12/722; H01R 24/50; H01Q 9/0407

(57) ABSTRACT

A ground plane is provided to a dielectric board. A high-frequency integrated circuit element is mounted on the dielectric board. A shield member electromagnetically shielding the high-frequency integrated circuit element is provided on the dielectric board. A first antenna element is provided on the dielectric board and at the same side as the shield member with respect to the ground plane. The first antenna element is connected to the high-frequency integrated circuit element by a first feed line. In a plan view, a portion of the first antenna element is disposed outside the shield member, a remaining portion of the first antenna element overlaps the shield member, or an entire range of the first antenna element is disposed outside the shield member, and a spaced distance from the shield member to the first antenna element is not greater than about ½ of a resonant wavelength of the first antenna element.

This application claims priority from Japanese Patent Application No. 2016-161614 filed on Aug. 22, 2016. The content of this application is incorporated herein by reference in its entirety.

### BACKGROUND OF THE DISCLOSURE

### 1. Field of the Disclosure

The present disclosure relates to a wireless module.

### 2. Description of the Related Art

A high-frequency wireless module obtained by modularizing an antenna element, a passive element, and a high-frequency integrated circuit element having a transmission/reception function in a high-frequency band, is publicly known (Japanese Unexamined Patent Application Publication No. 2007-129304). For example, electronic components such as a high-frequency integrated circuit element and a passive element are mounted on a board and sealed by a sealing member. A shield electrode is provided within the sealing member, and an antenna conductor such as a patch antenna is provided on the upper surface of the sealing member. The shield electrode for shielding the high-frequency integrated circuit element also serves as ground for the antenna.

The interval between the antenna conductor and the shield electrode that operates as ground influences the characteristics of the patch antenna. When the interval between the shield electrode and the antenna conductor is decreased, the operating band of the antenna becomes narrow. In order to widen the frequency band, the interval between the shield electrode and the antenna conductor has to be ensured to some extent. In the thickness direction of the board, since an antenna device including the antenna conductor and the shield electrode (ground) is stacked on a portion from the upper surface of the board to the shield electrode in which portion the high-frequency integrated circuit element is housed, it is difficult to reduce the thickness of the wireless module.

### BRIEF SUMMARY OF THE DISCLOSURE

Accordingly, it is an object of the present disclosure to provide a wireless module having a structure suitable for thickness reduction.

A wireless module according to a first aspect of the present disclosure includes: a dielectric board; a ground plane provided to the dielectric board; a high-frequency integrated circuit element mounted on the dielectric board; a shield member provided on the dielectric board and electromagnetically shielding the high-frequency integrated circuit element; a first antenna element provided on the dielectric board and disposed at the same side as the shield member with respect to the ground plane; and a first feed line connecting the first antenna element to the high-frequency integrated circuit element, wherein in a plan view, a portion of the first antenna element is disposed outside the shield member, and a remaining portion of the first antenna element overlaps with the shield member, or an entire range of the first antenna element is disposed outside the shield member, and a spaced distance from the shield member to the first antenna element is not greater than about ½ of a resonant wavelength of the first antenna element.

In the thickness direction of the dielectric board, a portion occupied by an antenna device including the first antenna element and the ground plane and a portion occupied by the shield member partially overlap each other. Therefore, it is possible to reduce the thickness of the wireless module as compared to a configuration in which the antenna device and the shield member are stacked in the thickness direction. Here, the resonant wavelength means an effective wavelength that takes into consideration the dielectric constant of the space between the first antenna element and the shield member, in the frequency band in which the first antenna element resonates.

In a wireless module according to a second aspect of the present disclosure, in addition to the configuration of the wireless module according to the first aspect, the shield member is connected to the ground plane.

It is possible to shield the high-frequency integrated circuit element by the ground plane and the shield member.

In addition to the configuration of the wireless module according to the first or second aspect, a wireless module according to a third aspect of the present disclosure includes: a second antenna element provided on the dielectric board and disposed at a side opposite to the shield member with respect to the ground plane; and a second feed line connecting the second antenna element to the high-frequency integrated circuit element.

By operating either the first antenna element or the second antenna element, it is possible to switch the direction of strong directivity.

In a wireless module according to a fourth aspect of the present disclosure, in addition to the configuration of the wireless module according to the first to third aspects, the first antenna element is a patch antenna and a portion of the patch antenna overlaps with the shield member in a plan view.

At a portion where the patch antenna and the shield member overlap each other, the patch antenna and the shield member capacitively couple to each other. Therefore, the amount of radio waves radiated from the edge of the patch antenna that overlaps with the shield member is smaller than the amount of radio waves radiated from the edge of the patch antenna that does not overlap the shield member. As a result, it is possible to regard the patch antenna approximately as one wave source, and thus it is possible to achieve wider directivity.

In a wireless module according to a fifth aspect of the present disclosure, in addition to the configuration of the wireless module according to the first to third aspects, the first antenna element is a monopole antenna disposed at a position at which a spaced distance from the shield member thereto is not greater than about ½ of the resonant wavelength of the first antenna element in a plan view.

It is possible to reduce the thickness of the wireless module as compared to a configuration in which a monopole antenna is stacked on the shield member.

In a wireless module according to a sixth aspect of the present disclosure, in addition to the configuration of the wireless module according to the first to third aspects, an end of the monopole antenna is short-circuited to the shield member.

Since the first antenna element operates as a folded monopole antenna, it is possible to increase the impedance of the first antenna element and widen the band of the first antenna element.

Other features, elements, characteristics and advantages of the present disclosure will become more apparent from the following detailed description of preferred embodiments of the present disclosure with reference to the attached drawings.

### BRIEF DESCRIPTION OF THE SEVERAL VIEWS OF THE DRAWINGS

FIG. 1 is a schematic cross-sectional view of a wireless module according to a first embodiment;

FIG. 2 is a schematic cross-sectional view of a wireless module according to a comparative example;

FIG. 3 is a schematic diagram of a wireless module according to a second embodiment;

FIG. 4 shows a plan view of a wireless module according to a third embodiment;

FIG. 5 is a schematic cross-sectional view of a wireless module according to a fourth embodiment; and

FIG. 6 is a schematic cross-sectional view of a wireless module according to a fifth embodiment.

### DETAILED DESCRIPTION OF THE DISCLOSURE

### First Embodiment

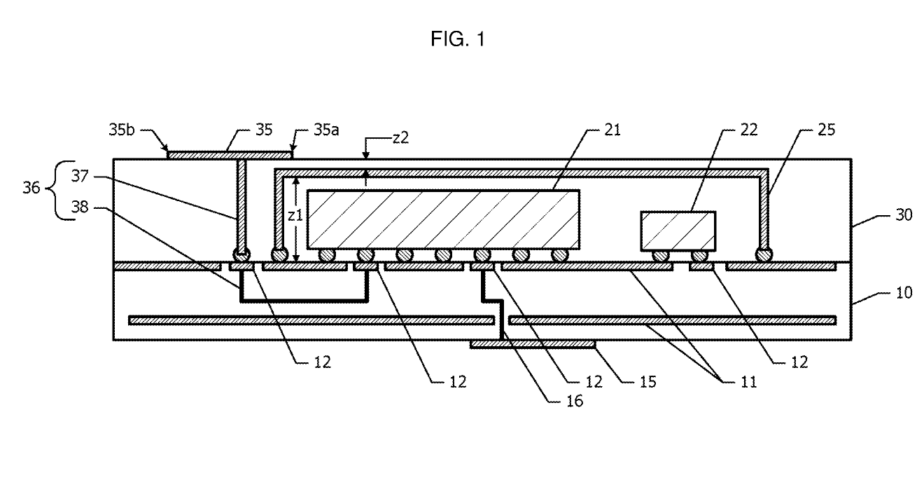

A wireless module according to a first embodiment will be described with reference to FIG. 1.

FIG. 1 is a schematic cross-sectional view of the wireless module according to the first embodiment. Ground planes 11 are provided to a dielectric board 10. The ground planes 11 may be disposed only within the dielectric board 10, or may be disposed both on the surface of the dielectric board 10 and within the dielectric board 10. FIG. 1 shows an example in which the ground planes 11 are disposed on the upper surface of the dielectric board 10 and within the dielectric board 10. A partial region of the ground plane 11 disposed on the upper surface is used as a ground land. Furthermore, signal lands 12 are provided on the upper surface of the dielectric board 10.

A high-frequency integrated circuit element 21 and a passive component 22 are mounted on the upper surface of the dielectric board 10. Part of terminals of the high-frequency integrated circuit element 21 is connected to the ground plane 11, and other part of the terminals is connected to the signal lands 12, respectively. Each terminal of the passive component 22 is also connected to the ground plane 11 or the signal land 12.

A shield member 25 provided on the dielectric board 10 covers the high-frequency integrated circuit element 21 and the passive component 22. The shield member 25 is connected to the ground plane 11 and electromagnetically shields the high-frequency integrated circuit element 21 and the passive component 22. For example, a shield case including an upper plate and side plates made of metal may be used as the shield member 25.

The shield member 25 may include a metal film and a plurality of conductor bars. The plurality of conductor bars forming the shield member 25 are disposed so as to surround the high-frequency integrated circuit element 21 and the passive component 22 in a plan view and project upward from the surface of the dielectric board 10. The metal film is disposed above the high-frequency integrated circuit element 21 and the passive component 22 and connected to the plurality of conductor bars in the vicinity of the outer periphery thereof.

A sealing member 30 made of resin is disposed on the dielectric board 10. When the shield case is used as the shield member 25, the sealing member 30 seals the shield member 25. When the shield member 25 includes the metal film and the plurality of conductor bars, the high-frequency integrated circuit element 21 and the passive component 22 are sealed by the sealing member 30, and the plurality of conductor bars are embedded within the sealing member 30. The upper surface of the metal film forming the shield member 25 is also covered by the sealing member 30.

A first antenna element 35 is provided on the upper surface of the sealing member 30. The first antenna element 35 is disposed at the same side as the shield member 25 with respect to the ground plane 11. For example, a patch antenna is used as the first antenna element 35. The first antenna element 35 is connected to the high-frequency integrated circuit element 21 via a first feed line 36. The first feed line 36 includes a conductor bar 37 extending within the sealing member 30 in a thickness direction, and a transmission line 38 provided in the dielectric board 10.

In a plan view, a portion of the first antenna element 35 is disposed outside the shield member 25, and the remaining portion of the first antenna element 35 overlaps with the shield member 25. The first antenna element 35 has, for example, a substantially square or rectangular planar shape, one edge 35a is disposed inside the shield member 25, and an edge 35b opposing to the edge 35a is disposed outside the shield member 25. The one edge 35a is referred to as inner edge, and the edge 35b opposing to the edge 35a is referred to as outer edge. The first antenna element 35 is excited in a direction perpendicular to the inner edge 35a and the outer edge 35b inside and outside the shield member 25 (the right-left direction in FIG. 1).

A second antenna element 15 is provided on the lower surface of the dielectric board 10. The second antenna element 15 is disposed at a side opposite to the shield member 25 with respect to the ground plane 11. For example, a patch antenna is used as the second antenna element 15. The second antenna element 15 is connected to the high-frequency integrated circuit element 21 via a second feed line 16 provided in the dielectric board 10.

The first antenna element 35 radiates radio waves upward with respect to the dielectric board 10 when being supplied with power from the high-frequency integrated circuit element 21. The second antenna element 15 radiates radio waves downward with respect to the dielectric board 10 when being supplied with power from the high-frequency integrated circuit element 21.

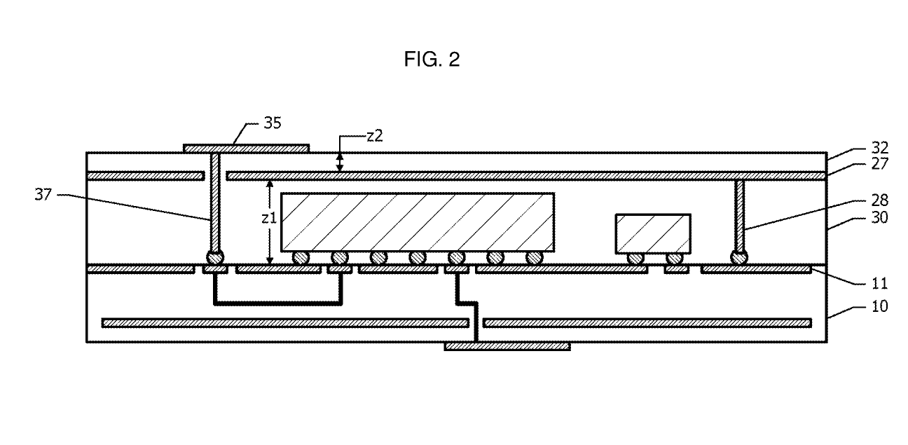

Next, advantageous effects of the wireless module according to the first embodiment shown in FIG. 1 will be described in comparison with a comparative example shown in FIG. 2.

FIG. 2 is a schematic cross-sectional view of a wireless module according to the comparative example. In the wireless module according to the comparative example, a shield film 27 is used instead of the shield member 25 in FIG. 1. The shield film 27 is disposed over substantially the entire range of the upper surface of the sealing member 30. The shield film 27 is connected to the ground plane 11 via a ground connection via 28.

A dielectric layer 32 is disposed on the shield film 27. The first antenna element 35 is disposed on the upper surface of the dielectric layer 32. The conductor bar 37 for connecting the first antenna element 35 to the high-frequency integrated circuit element 21 penetrates the dielectric layer 32, the shield film 27, and the sealing member 30 in the thickness direction. A cavity is provided in the shield film 27 and at a position where the conductor bar 37 penetrates the shield film 27, so that the shield film 27 and the conductor bar 37 are insulated from each other. The shield film 27 operates as ground for the first antenna element 35.

In the first embodiment shown in FIG. 1, the interval from the ground plane 11 provided on the upper surface of the dielectric board 10 to the upper surface of the shield member 25 is represented by z1, and the interval from the upper surface of the shield member 25 to the first antenna element 35 is represented by z2. In the comparative example shown in FIG. 2, the interval from the ground plane 11 provided on the upper surface of the dielectric board 10 to the shield film 27 corresponds to the interval z1 (FIG. 1) in the first embodiment, and the interval from the shield film 27 to the first antenna element 35 corresponds to the interval z2 (FIG. 1) in the first embodiment.

In the first embodiment shown in FIG. 1, the interval between the outer edge 35b of the first antenna element 35 and the ground plane 11 provided on the upper surface of the dielectric board 10 is nearly equal to z1+z2, and the interval between the inner edge 35a and the upper surface of the shield member 25 is equal to z2. The extension of a fringing electric field spreading outward from the outer edge 35b of the first antenna element 35 depends on the interval z1+z2. On the other hand, in the comparative example shown in FIG. 2, each of the intervals between the four edges of the first antenna element 35 and the shield film 27 is equal to z2. The extension of a fringing electric field spreading outward from one edge of the first antenna element 35 according to the comparative example is influenced by the interval z2 but is not influenced by the interval z1 below the shield film 27.

In the first embodiment, the fringing electric field spreading outward from the outer edge 35b of the first antenna element 35 more widely spreads due to the influence of the interval z1, and thus the effective size of the first antenna element 35 increases. As a result, in the first antenna element 35 according to the first embodiment, it is possible to achieve more favorable characteristics as compared to the first antenna element 35 according to the comparative example.

In the comparative example, in order to ensure the effective size of the first antenna element 35 equal to that in the first embodiment, the interval z2 has to be made larger than the corresponding interval z2 of the wireless module according to the first embodiment. When the interval z2 is increased, the wireless module becomes thick. In other words, it is possible to reduce the thickness of the wireless module according to the first embodiment as compared to the wireless module according to the comparative example.

In addition, under a condition that the interval z2 of the wireless module according to the first embodiment is nearly equal to the corresponding interval z2 of the wireless module according to the comparative example and the effective size of the first antenna element 35 is the same, the first antenna element 35 according to the first embodiment is smaller than the first antenna element 35 according to the comparative example. The resonant frequency or the operating frequency of the first antenna element 35 depends on the effective size of the first antenna element 35. Therefore, in the wireless module according to the first embodiment, it is possible to reduce the size of the first antenna element 35 by making the effective size of the first antenna element 35 the same while keeping the resonant frequency or the operating frequency constant, as compared to the comparative example.

Furthermore, in the wireless module according to the first embodiment shown in FIG. 1, the interval z2 between the inner edge 35a of the first antenna element 35 and the shield member 25, which serves as ground, is smaller than the interval z1 between the outer edge 35b and the ground plane 11. By the inner edge 35a of the first antenna element 35 and the shield member 25 capacitively coupling to each other, the amount of radio waves radiated from the inner edge 35a becomes smaller than that from the outer edge 35b. On the other hand, in the wireless module according to the comparative example shown in FIG. 2, each of the intervals from a pair of edges opposing to each other to the shield member 25, which serves as ground, is equal to z2. Thus, the amounts of radio waves radiated from the pair of edges are nearly equal to each other. That is, two wave sources are present.

In the first embodiment, when the amount of radio waves radiated from the inner edge 35a of the first antenna element 35 is smaller than that from the outer edge 35b, it is possible to substantially regard the first antenna element 35 as a single wave source. Therefore, in the wireless module according to the first embodiment, it is possible to achieve wider directivity characteristics.

Furthermore, it is made possible to control the directivity and widen the band on the basis of the positional relationship or connection between the first antenna element 35 and the shield member 25. In addition, the second antenna element 15 is disposed below the ground plane 11, and the first antenna element 35 is disposed above the ground plane 11. Therefore, it is possible to direct a main lobe of the directivity characteristics of the wireless module in either the downward direction or the upward direction with respect to the ground planes 11.

When radio waves are radiated only upward with respect to the dielectric board 10, the second antenna element 15 and the second feed line 16 may be omitted.

### Second Embodiment

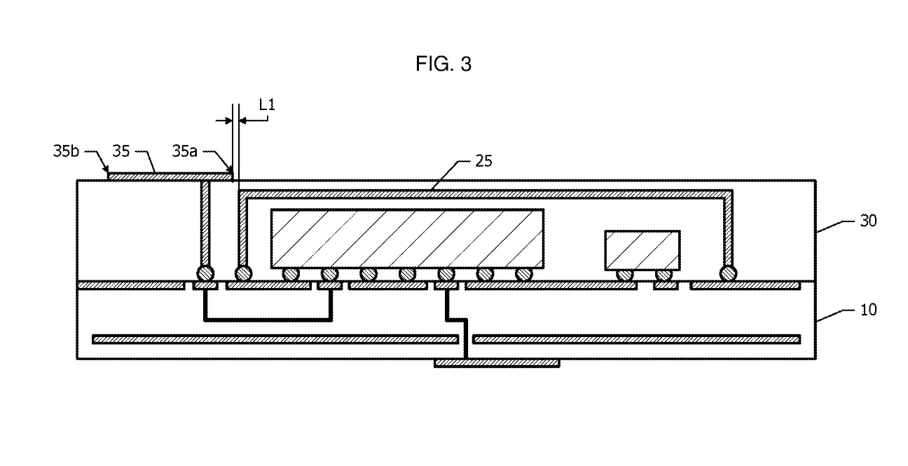

Next, a wireless module according to a second embodiment will be described with reference to FIG. 3. Hereinafter, the difference from the first embodiment shown in FIG. 1 will be described, and the description of the configuration common with the first embodiment is omitted.

FIG. 3 is a schematic diagram of the wireless module according to the second embodiment. In the first embodiment, a portion of the first antenna element 35 overlaps with the shield member 25 in a plan view. However, in the second embodiment, the entire range of the first antenna element 35 is disposed outside the shield member 25 in a plan view. When the spaced distance from the shield member 25 to the first antenna element 35 in an in-plane direction is represented by L1, the spaced distance L1 is not smaller than about 0.

The positional relationship between the outer edge 35b of the first antenna element 35 and the ground plane 11 is the same as that in the first embodiment. Unlike the structure of the first embodiment, the edge 35a opposing to the outer edge 35b is not disposed inside the shield member 25, but the interval from the edge 35a to the shield member 25 is set so as to be smaller than the interval from the edge 35b to the ground plane 11. Therefore, the substantially same advantageous effects as those of the first embodiment are also achieved in the second embodiment.

Next, a preferable range of the spaced distance L1 will be described. When the spaced distance L1 is excessively large, the effect caused by the first antenna element 35 and the shield member 25 capacitively coupling to each other is not achieved. In order to achieve the effect caused by the first antenna element 35 and the shield member 25 capacitively coupling to each other, the spaced distance L1 is preferably not greater than about ½ of the resonant wavelength of the first antenna element 35. Here, the resonant wavelength means an effective wavelength that takes into consideration the dielectric constant of the space between the first antenna element 35 and the shield member 25, in the frequency band in which the first antenna element 35 resonates.

### Third Embodiment

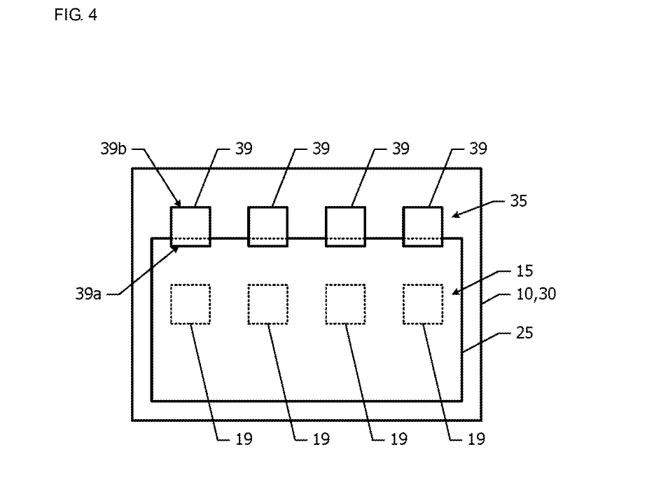

Next, a wireless module according to a third embodiment will be described with reference to FIG. 4. Hereinafter, the difference from the wireless module according to the first embodiment shown in FIG. 1 will be described, and the description of the configuration common with the wireless module according to the first embodiment is omitted.

FIG. 4 shows a plan view of the wireless module according to the third embodiment. The first antenna element 35 is disposed on the upper surface of the sealing member 30. The first antenna element 35 has a patch array antenna structure in which a plurality of radiation electrodes 39 are aligned in a row. Each radiation electrode 39 has a substantially square or rectangular planar shape. In a plan view, one edge 39a of each radiation electrode 39 is disposed inside the shield member 25, and an edge 39b opposing to the edge 39a is disposed outside the shield member 25. The other two edges intersect with the contour line of the shield member 25 in a plan view.

The second antenna element 15 is disposed on the lower surface of the dielectric board 10. The second antenna element 15 also has a patch array antenna structure in which a plurality of radiation electrodes 19 are aligned in a row. It is possible to cause the first antenna element 35 and the second antenna element 15 to operate as a phased array antenna by controlling the phase of a high-frequency signal supplied to each radiation electrode 39 or 19.

### Fourth Embodiment

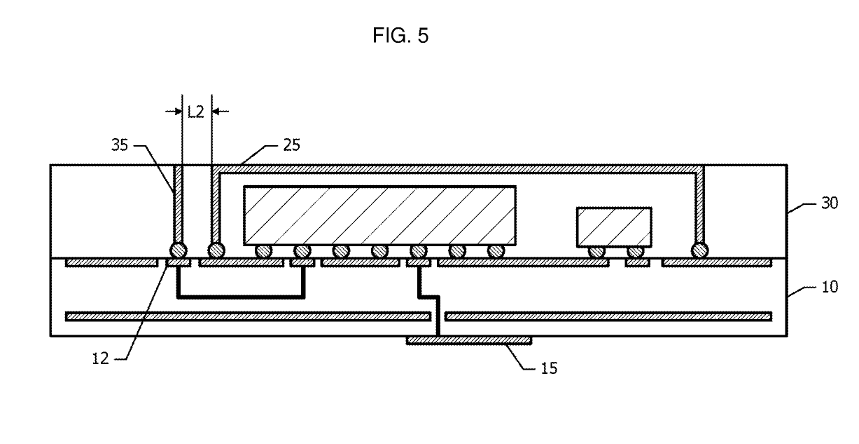

Next, a wireless module according to a fourth embodiment will be described with reference to FIG. 5. Hereinafter, the difference from the wireless module according to the first embodiment shown in FIG. 1 will be described, and the description of the configuration common with the wireless module according to the first embodiment is omitted.

FIG. 5 is a schematic cross-sectional view of the wireless module according to the fourth embodiment. In the first embodiment, a patch antenna is used as the first antenna element 35. However, in the present embodiment, a monopole antenna is used as the first antenna element 35. The first antenna element 35 is composed of a conductor bar connected to the signal land 12 on the dielectric board 10. The conductor bar extends in a direction parallel to the thickness direction of the dielectric board 10 and is embedded in the sealing member 30.

The length of the monopole antenna as the first antenna element 35 is nearly equal to the thickness of the sealing member 30. The first antenna element 35 is disposed near the shield member 25 in a plan view, and the side plate of the shield member 25 serves as a reflection plate for the first antenna element 35. In order to cause the side plate of the shield member 25 to serve as a reflection plate, a spaced distance L2 from the shield member 25 to the first antenna element 35 is preferably not greater than about ½ of the resonant wavelength of the first antenna element 35. The resonant wavelength of the first antenna element 35 is equal to about 4 times of the length of the monopole antenna.

Next, advantageous effects of the wireless module according to the fourth embodiment will be described. The first antenna element 35 of the wireless module according to the fourth embodiment has strong directivity in the direction in which an end surface of the dielectric board 10 faces. In addition, similarly to the first embodiment, the second antenna element 15 has strong directivity in the direction in which the lower surface of the dielectric board 10 faces. As described above, in the fourth embodiment, it is possible to have strong directivity in one of or both of the direction in which the end surface of the dielectric board 10 faces and the direction in which the lower surface of the dielectric board 10 faces.

In addition, in the fourth embodiment, it is possible to reduce the thickness of the entire wireless module as compared to a structure in which a monopole antenna is stacked on the shield member 25.

In FIG. 5, an example is shown in which the height of the shield member 25 is nearly equal to the length of the monopole antenna. However, it is not necessary to make the heights of the shield member 25 and the monopole antenna equal to each other.

### Fifth Embodiment

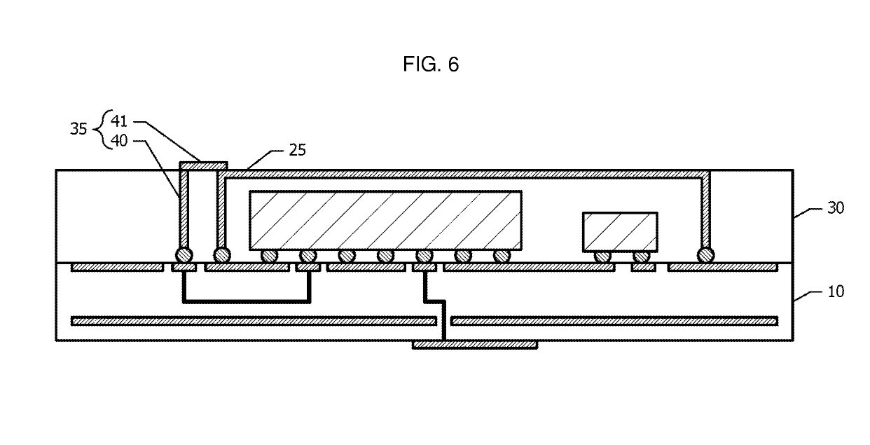

Next, a wireless module according to a fifth embodiment will be described with reference to FIG. 6. Hereinafter, the difference from the wireless module according to the fourth embodiment shown in FIG. 5 will be described, and the description of the configuration common with the wireless module according to the fourth embodiment is omitted.

FIG. 6 is a schematic cross-sectional view of the wireless module according to the fifth embodiment. In the fourth embodiment, a monopole antenna is used as the first antenna element 35. However, in the fifth embodiment, a folded monopole antenna is used as the first antenna element 35. Specifically, the first antenna element 35 includes: a conductor bar 40 extending in the thickness direction within the sealing member 30; and a short-circuit member 41 which short-circuits an end (upper end) of the conductor bar 40 to the shield member 25.

The end of the conductor bar 40 and the upper surface of the shield member 25 are exposed on the upper surface of the sealing member 30. The short-circuit member 41 is disposed so as to extend from the end of the conductor bar 40 exposed on the upper surface of the sealing member 30 to the upper surface of the shield member 25 exposed on the upper surface of the sealing member 30.

In the fifth embodiment, by using the folded monopole antenna as the first antenna element 35, it is possible to increase the impedance of the first antenna element 35 and widen the band of the first antenna element 35 as compared to the fourth embodiment.

Each embodiment is illustrative, and it is needless to say that the components shown in the different embodiments may be partially replaced or combined. The same advantageous effects achieved by the same configuration in multiple embodiments are not mentioned successively in each embodiment. Furthermore, the present disclosure is not limited to the above-described embodiments. For example, it is obvious to a person skilled in the art that various changes, modifications, combinations, etc. may be made.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A wireless module comprising:
a dielectric board;
a ground plane provided to the dielectric board;
a high-frequency integrated circuit element mounted on the dielectric board;
a shield member provided on the dielectric board and electromagnetically shielding the high-frequency integrated circuit element;
a first antenna element provided on the dielectric board and disposed at a same side as the shield member with respect to the ground plane; and
a first feed line connecting the first antenna element to the high-frequency integrated circuit element, wherein
in a plan view, a portion of the first antenna element is disposed outside the shield member, and
a remaining portion of the first antenna element overlaps with the shield member, or an entire range of the first antenna element is disposed outside the shield member, and a spaced distance from the shield member to the first antenna element is not greater than about ½ of a resonant wavelength of the first antenna element.

2. The wireless module according to claim 1, wherein the shield member is connected to the ground plane.

3. The wireless module according to claim 1, further comprising:
a second antenna element provided on the dielectric board and disposed at a side opposite to the shield member with respect to the ground plane; and
a second feed line connecting the second antenna element to the high-frequency integrated circuit element.

4. The wireless module according to claim 1, wherein the first antenna element is a patch antenna and a portion of the patch antenna overlaps with the shield member in a plan view.

5. The wireless module according to claim 1, wherein the first antenna element is a monopole antenna disposed at a position at which a spaced distance from the shield member thereto is not greater than about ½ of the resonant wavelength of the first antenna element in a plan view.

6. The wireless module according to claim 5, wherein an end of the monopole antenna is short-circuited to the shield member.

7. The wireless module according to claim 2, further comprising:
a second antenna element provided on the dielectric board and disposed at a side opposite to the shield member with respect to the ground plane; and
a second feed line connecting the second antenna element to the high-frequency integrated circuit element.

8. The wireless module according to claim 2, wherein the first antenna element is a patch antenna and a portion of the patch antenna overlaps with the shield member in a plan view.

9. The wireless module according to claim 3, wherein the first antenna element is a patch antenna and a portion of the patch antenna overlaps with the shield member in a plan view.

10. The wireless module according to claim 2, wherein the first antenna element is a monopole antenna disposed at a position at which a spaced distance from the shield member thereto is not greater than about ½ of the resonant wavelength of the first antenna element in a plan view.

11. The wireless module according to claim 3, wherein the first antenna element is a monopole antenna disposed at a position at which a spaced distance from the shield member thereto is not greater than about ½ of the resonant wavelength of the first antenna element in a plan view.
